(19) United States
(12) Patent Application Publication
(10) Pub. No.: US 2024/0102147 A1
(43) Pub. Date: Mar. 28, 2024

(54) APPLYING A TRANSPARENT CONDUCTIVE FILM TO FLUORINE-DOPED TIN OXIDE

(71) Applicant: nexTC Corporation, Corvallis, OR (US)

(72) Inventors: Cory K. Perkins, Salem, OR (US); Jennie Amador, Philomath, OR (US); Douglas A. Keszler, Corvallis, OR (US)

(21) Appl. No.: 18/477,463

(22) Filed: Sep. 28, 2023

Related U.S. Application Data
(60) Provisional application No. 63/377,494, filed on Sep. 28, 2022.

(51) Int. Cl. C23C 14/04; C23C 14/24; C23C 14/52; C23C 14/54; C23C 14/56

(52) U.S. Cl. CPC C23C 14/042; C23C 14/24; C23C 14/52; C23C 14/543; C23C 14/546; C23C 14/568

(57) ABSTRACT

Examples are disclosed relate to the application of films of transparent conductors over fluorine-doped tin oxide (FTO) to form a multi-layer structure comprising a lower sheet resistance and smoother surface, while exhibiting a higher transparency, than a single thicker FTO with an equivalent thickness. Various compositions of transparent conductor may be deposited using such solutions. Examples include Sn:In₂O₃, Ti:In₂O₃, Cd₂SnO₄, and combinations of two or more such materials. One example provides optical device, comprising a substrate, an FTO film on the substrate, and a film of a transparent conductor on the FTO film.

### CROSS-REFERENCE TO RELATED APPLICATION

This application claims priority to U.S. Provisional Patent Application Ser. No. 63/377,494, filed Sep. 28, 2022 and titled APPLYING A TRANSPARENT CONDUCTIVE FILM TO FLUORINE-DOPED TIN OXIDE. The entire disclosure of this provisional patent application is hereby incorporated by reference in its entirety.

### BACKGROUND

Optically transparent electrically conductive materials have many uses. For example, solar cells include an optically transparent conductive layer through which solar radiation passes before being absorbed and generating an electron/hole pair at a semiconductor junction. The optically transparent conductive layer acts as a current collector to collect charge carriers generated by this process. Also, optically transparent electrically conductive materials are used in display devices, such as liquid crystal display (LCD) panels and organic light emitting diode (OLED) display panels as pixel electrodes. Electric fields generated across each pixel by control of the pixel electrodes are used to control the emission of light the display panel through the transparent pixel electrodes.

### BRIEF DESCRIPTION OF THE DRAWINGS

FIG. 1 shows a flow diagram of an example method for coating a fluorine-doped tin oxide (FTO) film on a substrate.

FIG. 2 shows transmissivity (upper line) and reflectivity (lower line) data for uncoated 8 ohms/sq FTO.

FIG. 3 shows transmissivity (upper line) and reflectivity (lower line) data for an 8 ohms/sq FTO coated with an 89+/−2 nm thick indium tin oxide (ITO) film.

FIG. 4 shows transmissivity (upper line) and reflectivity (lower line) data for an 8 ohms/sq FTO coated with a 68+/−2 nm thick ITO film.

FIG. 5 shows transmissivity (upper line) and reflectivity (lower line) data for an 8 ohms/sq FTO coated with a 48+/−4 nm thick ITO film.

FIG. 6 shows an image of atomic force microscopy (AFM) data for an uncoated 8 ohms/sq FTO film.

FIG. 7 shows an image of AMF data for an 8 ohms/sq FTO coated with an ITO film having a thickness of 93+/−17 nm.

FIG. 8 schematically shows an example optical device that includes an FTO film coated with an ITO film.

### DETAILED DESCRIPTION

As mentioned above, optically transparent electrically conductive materials (hereinafter referred to as transparent conductors) have many uses. One commonly used transparent conductor is fluorine-doped tin oxide (FTO). FTO is commonly provided in the form of a thin film on a glass substrate. However, current FTO films may have properties that pose challenges for some uses. For example, films of FTO may have resistances that are higher than metallic conductors. This can lead to increased power usage compared to metallic conductors. Further, films of FTO also can have a relatively high degree of roughness. As an example, a film of FTO with a sheet resistance of approximately 8 ohms/square may have a roughness on the order of 33.5+/−0.2 nm. This roughness may cause some scattering of light, which may lower an efficiency of a device using the FTO film. In some examples, depending on device structures and deposition methods, a FTO film comprising a relatively high roughness may not be compatible with manufacturing devices with thin active layers. In the case of solar cells, this roughness may reduce an amount of light that can be used to generate charge carriers. In the case of display devices, this roughness can reduce an apparent image intensity.

A sheet resistance of an FTO film may be lowered by using a thicker layer of FTO. However, thicker FTO layers can cause reduced optical transparency. This can reduce an amount of light that reaches a semiconductor junction in a solar cell, and thus can reduce an efficiency of the solar cell. Likewise, reduced optical transparency also can reduce an efficiency of a display device, as more power may be used to generate light to compensate for the reduced transparency. Also, the use of a thicker FTO film may not address issues with surface roughness, as roughness arises from chemical vapor deposition (CVD) methods used to form the films. Additionally, CVD films typically exhibit relatively higher roughness for relatively thicker films.

Accordingly, examples are disclosed that relate to the application of films of transparent conductors over FTO or other materials to address concerns such as those described above. Briefly, a solution of reagents for forming a film of a transparent conductive material is applied to a substrate comprising a film of FTO or other transparent conductor. The solution may be deposited using a variety of methods, such as slot-die coating, doctor blade coating, dip coating, or spin coating. After applying the reagent solution, the substrate is heated to cure the film, thereby causing the reagents to react on the substrate and form a solid-phase film of a transparent conductor over the FTO or other material. Various compositions of transparent conductor may be deposited using such solutions. Examples include Sn:In₂O₃, Ti:In₂O₃, Cd₂SnO₄, and combinations of two or more such materials. The resulting multi-layer structure may comprise a lower sheet resistance and smoother surface than a single thicker FTO with an equivalent thickness, while exhibiting a higher transparency. A relatively lower sheet resistance can help improve power efficiency in optical devices. Additionally, by smoothing the surface of the CVD-deposited transparent conductor, the disclosed examples can provide a film of transparent conductor with less light scattering than a CVD-deposited transparent conductor lacking an overlying film of a transparent conductor. This can help improve transmissivity of the film of transparent conductor, which can improve efficiency in optical devices. By forming a smoother surface, the disclosed examples also can provide for relatively thicker transparent conductors with better conductivity than thinner films, while avoiding increased roughness that is typically associated with such thicker films.

The examples below are described with regard to the formation of an indium tin oxide (Sn:In₂O₃, also referred to as ITO) film over a CVD-deposited FTO film. However, films of Ti:In₂O₃, Cd₂SnO₄, and combinations of two or more of any of these materials (including ITO) may be used. Further, the film of transparent conductor can be deposited on any suitable CVD-deposited transparent conductive oxide (TCO), such as FTO, ITO, antimony-doped tin oxide (Sb—SnO₂, ATO), and aluminum-doped zinc oxide (Al—ZnO, AZO). A multi-layer structure comprising a film of transparent conductor (e.g., Sn:In₂O₃, Ti:In₂O₃, Cd₂SnO₄) deposited onto a CVD-deposited TCO film also can be referred to as a TCO film stack.

In further examples, a solution-processed FTO film can be deposited onto a CVD-deposited FTO film. This can improve transmissivity, lower sheet resistance, and provide a smoother surface than a CVD-deposited FTO film with similar thickness. The solution-processed FTO film can be formed using any suitable method. As an example, an FTO precursor solution can be made by dissolving SnCl₂ in tetrahydrofuran (THF) and then adding a fluorinating agent. Any suitable fluorinating agent can be used. Examples include trifluoroacetic acid, triethylamine trihydrofluoride, and hydrofluoric acid (HF). In some examples, the ratio of F⁻ ions to metal ions in the FTO precursor solution is between 5% to 20%. In other examples, a ratio outside this range can be used. Further, in other examples, salts other than tin chloride and/or solvents other than THF can be used.

Transparent conductive film precursor solutions, methods of preparing precursor solutions, and methods of applying the precursor solutions to form transparent conductive films are described in US Patent Application Publication No. 2022/0102639, the disclosure of which is incorporated by reference in its entirety. The example conductive film precursor solutions can include any suitable precursor(s). Precursor solutions for forming Sn:In₂O₃ films can include In₂O₃ precursors and SnO₂ precursors. Precursor solutions for forming Ti:In₂O₃ films can include In₂O₃ precursors and TiO₂ precursors. Further, precursor solutions for forming Cd₂SnO₄ films can include CdO precursors and SnO₂ precursors. Examples of In₂O₃ precursors include indium nitrate, indium halides, and combinations thereof. Examples of SnO₂ precursors include tin halides (e.g., tin fluoride, tin chloride, tin bromide, or tin iodide), tin chloride hydrate, tin nitrate, tin nitrate hydrate, tin acetate, tin sulfate, and combinations thereof. Examples of TiO₂ precursors include titanium halides, such as titanium fluoride, titanium chloride, titanium bromide, titanium iodide, and combinations thereof. Examples of CdO precursors include cadmium halides, such as cadmium fluoride, cadmium chloride, cadmium bromide, cadmium iodide, and combinations thereof. In some examples, precursor compounds are selected to be water soluble. For example, one or more precursors can be dissolved in water to make a precursor solution. In some examples, heat and/or agitation can be used to help dissolve the precursor compounds. A precursor solution can comprise selected ions at any suitable concentration. In some examples, a precursor solution can comprise an In³⁺ concentration of 0.1M to 0.9M. In some examples, a precursor solution can comprise a Sn²⁺ concentration of 0.1M to 0.9M. In other examples, ion concentrations outside these ranges can be used.

As mentioned above, the film of transparent conductor can be deposited onto a FTO film or other conductive material (e.g., ATO or AZO) to form a TCO film stack. In other examples, the film of transparent conductor can be deposited onto any other suitable substrate. Examples include silicon, silica (SiO₂), a glass, a metal, a metal alloy, an optical crystal, a laser crystal, a ceramic substrate, and substrates comprising a combination of such materials. In some examples, the substrate is a silicon wafer. In some examples, the substrate is a hydrophobic or hydrophilic glass, such as silicate glass. In some examples, a TCO film stack is deposited onto a glass substrate and a photoactive material is deposited onto the TCO-coated glass to form a solar cell. In some examples, the film of transparent conductor can be deposited onto a photoactive material to form a solar cell. Examples of photoactive materials include silicon, perovskite materials and cadmium telluride (CdTe). Examples of perovskite materials include methylammonium lead halide and inorganic cesium lead halide. In some more specific examples, a perovskite tandem solar panel comprises an FTO film and a film of transparent conductor deposited onto the FTO film to smooth the surface and lower the sheet resistance of the FTO film.

The film of transparent conductor can be deposited on the substrate using any suitable method. Examples include spin coating, roll coating, spray coating, ink-jet printing, mist deposition, slot-die coating, dip coating, and doctor blade deposition. As mentioned above, after deposition, the film can be exposed to heat to cure the film. Example processing temperatures include temperatures of 50° C. to 1000° C. or greater. In some examples, heating the film comprises exposing the film to a temperature below the annealing temperature of the film. This can help evaporate solvent, for example. In some examples, heating the film can additionally or alternatively comprise annealing the film. For example, the film can be processed at a first temperature for a first period of time and then processed at a second temperature for a second period of time.

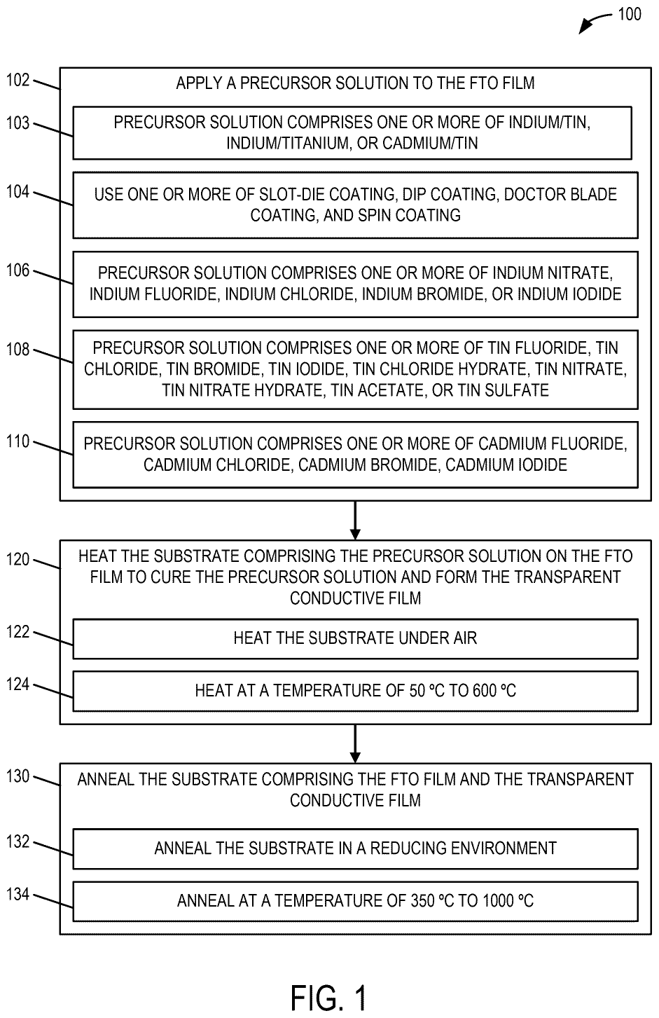

FIG. 1 shows a flow diagram of an example method 100 for coating a FTO film on a substrate. At 102, method 100 comprises applying a precursor solution to the FTO film. In some examples, at 103, the precursor solution comprises one or more of indium/tin, indium/titanium, or cadmium/tin. In some examples, at 104, the method comprises applying the precursor solution using one or more of slot-die coating, dip coating, doctor blade coating, and spin coating. In some examples, at 106, the precursor solution comprises one or more of indium nitrate, indium fluoride, indium chloride, indium bromide, or indium iodide. In some examples, at 108, the precursor solution comprises one or more of tin fluoride, tin chloride, tin bromide, tin iodide, tin chloride hydrate, tin nitrate, tin nitrate hydrate, tin acetate, or tin sulfate. In some examples, at 110, the precursor solution comprises one or more of cadmium fluoride, cadmium chloride, cadmium bromide, cadmium iodide.

Method 100 further comprises, at 120, heating the substrate comprising the precursor solution on the FTO film to cure the precursor solution and form the transparent conductive film. In some examples, at 122, method 100 comprises heating the substrate under air. In other examples, the substrate can be heated under an inert gas (e.g., Ar) or heated in vacuum. In some examples, at 124, the substrate is heated at a temperature of 50° C. to 600° C.

Method 100 further comprises, at 130, annealing the substrate comprising the FTO film and the transparent conductive film. In some examples, at 132, method 100 comprises annealing the substrate in a reducing environment. For example, a forming-gas (5% H₂-95% Ar or N₂) can be used. In some examples, at 134, the substrate is annealed at a temperature of 350° C. to 1000° C.

The deposited film of transparent conductor can comprise any suitable thickness. Examples include film having a thickness within a range of 3 to 3000 nm. In some examples, the film of transparent conductor comprises a thickness that is 350 nm or less, 300 nm or less, 250 nm or less, or even 100 nm or less. In other examples, a thickness outside of these ranges can be used. As sheet resistance can depend on thickness, relatively thicker films can help reduce the sheet resistance. In some examples, the uncoated CVD-deposited FTO film comprises a sheet resistance of approximately 8 ohms/sq (e.g., 7.5 to 9.0 ohms/sq). In some such examples, after coating with a TCO film, the coated FTO film comprises a sheet resistance of 6.0 to 8.5 ohms/sq. In some examples, the uncoated CVD-deposited FTO film comprises a sheet resistance of approximately 15 ohms/sq (e.g., 14.0 to 16.0 ohms/sq). In some such examples, after coating with a TCO film, the coated FTO film comprises a sheet resistance of 11.0 to 13.5 ohms/sq. In some examples, the sheet resistance of the multi-layer structure is within a range of 6.0 to 8.0 ohms/sq. In other examples, the sheet resistance may be outside these ranges. In some examples, coating a CVD-deposited FTO film with a film of transparent conductor can lower the sheet resistance of the resultant multi-layer structure by 10% or more, 20% or more, or even 30% or more. Specific examples are described in experimental results below.

Additionally, a film of transparent conductor deposited over a CVD-deposited FTO film can comprise a lower surface roughness than the underlying FTO film. For example, an uncoated FTO film can comprise a surface roughness in a range of 30 to 50 nm. After depositing a film of transparent conductor, the TCO film stack can comprise a surface roughness in a range of 0.5 to 30 nm. In some examples, the of the film of transparent conductor comprises a surface roughness of 20 nm or less. In some examples, the of the film of transparent conductor comprises a surface roughness of 10 nm or less. In some examples, the of the film of transparent conductor comprises a surface roughness of 5 nm or less.

The resulting multi-layer structure may be incorporated into any suitable optical device. Examples include solar cells (e.g., a perovskite tandem solar panel) and displays, such as light-emitting diodes (LEDs) and organic LEDs (OLEDs). As an example, a solar cell can include a photoactive material deposited onto TCO-coated glass substrate. As the multi-layer structure can exhibit a higher transparency than a single, thicker FTO film, such examples can help provide a solar cell with greater efficiency.

### Experimental Results

An Sn:In₂O₃ (indium tin oxide (ITO)) precursor solution was prepared as disclosed in the above-referenced US Patent Application Publication No. 2022/0102639. Examples of precursors are listed above. Prior to application of the precursor solution to a FTO-coated glass substrate, the ITO precursor solution was filtered using a 0.2 μm syringe filter with PTFE housing and filter membrane. The FTO-coated glass (NSG TEC glass) was cleaned prior to deposition by rinsing with acetone, ethanol, and 18 MΩ deionized water. After cleaning, the FTO film on the substrate was made hydrophilic, for example, by a UV ozone (Novascan) treatment or O₂ plasma treatment. The precursor solution was deposited on the FTO using slot-die coating. A stage temperature of the slot-die coating apparatus was set to 100° C., 100 μm gap height, stage speed of 1 mm/s, and flow rate of 1 mL/s. The deposited precursor film was cured at 550° C. in a furnace under air, and allowed to cool slowly in the furnace. The film was then annealed under an atmosphere comprising a forming-gas (5% H₂-95% Ar or N₂) at 500° C. for 30 min.

Table 1 shows differences in sheet resistance for uncoated FTO/glass and FTO/glass coated with an ITO film.

TABLE 1

| | Sheet resistance | |
|---|---|---|
| Sample Identity | (ohms/square) | Thickness of ITO (nm) |
| Uncoated 15 ohms/sq FTO | 14.8 +/− 0.3 | N/A |
| Coated 15 ohms/sq FTO | 11.08 +/− 0.1 | 246 +/− 33 |
| Uncoated 8 ohms/sq FTO | 8.52 +/− 0.02 | N/A |
| Coated 8 ohms/sq FTO | 6.3 +/− 0.02 | 180 +/− 14 |

As shown in Table 1, coating the FTO with ITO provided a lower sheet resistance. F

Table 2 shows more data regarding differences in sheet resistance for uncoated FTO/glass and FTO/glass coated with an ITO film, and illustrates decreasing sheet resistance with increasing thickness.

TABLE 2

| | Sheet resistance | |
|---|---|---|
| Sample Identity | (ohms/square) | Thickness of ITO (nm) |
| Uncoated 15 ohms/sq FTO | 14.8 +/− 0.3 | N/A |
| Uncoated 8 ohms/sq FTO | 8.52 +/− 0.02 | N/A |
| Coated 15 ohms/sq FTO | 13.2 +/− 0.1 | 140 +/− 4 |
| Coated 15 ohms/sq FTO | 11.08 +/− 0.1 | 246 +/− 33 |
| Coated 8 ohms/sq FTO | 8.2 +/− 0.1 | 48 +/− 4 |
| Coated 8 ohms/sq FTO | 8.0 +/− 0.1 | 68 +/− 2 |
| Coated 8 ohms/sq FTO | 7.8 +/− 0.1 | 89 +/− 2 |

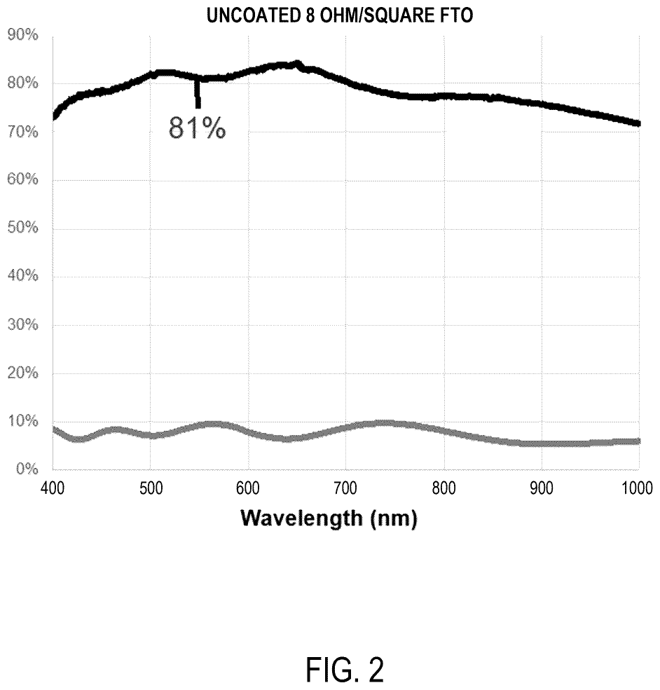

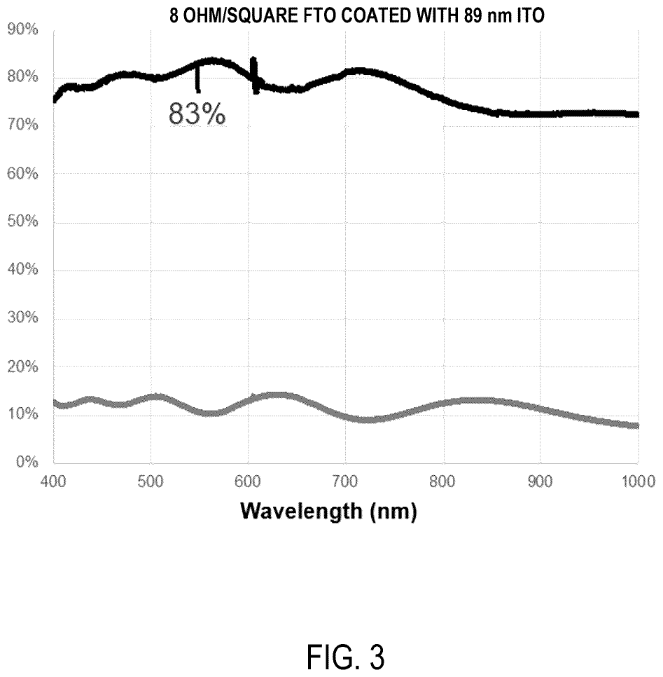

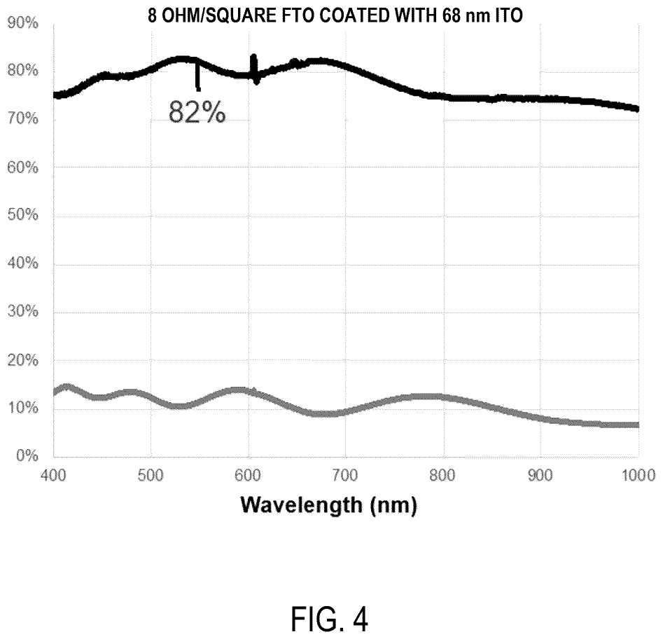

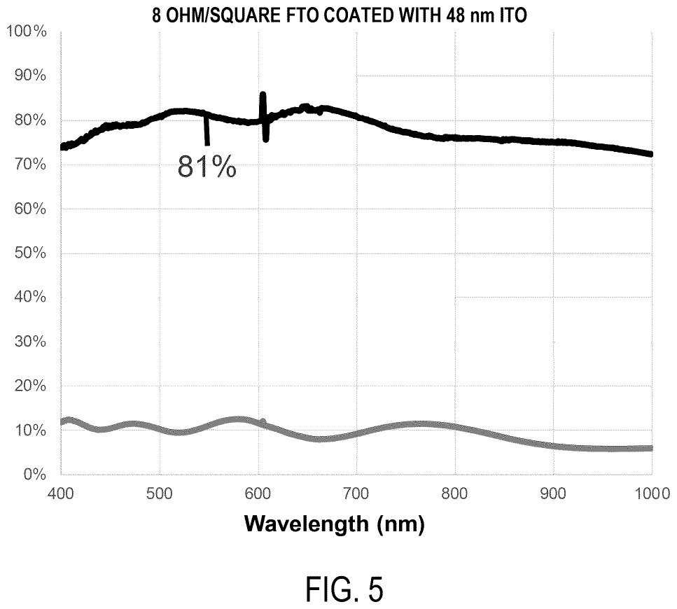

As shown in Table 2, the difference in sheet resistance between uncoated and coated samples is repeatable and demonstrated across multiple samples. Further, the reduction in the sheet resistance is controllable and tunable. Additionally, the increase in thickness does not detrimentally impact the optical transmissivity of the samples. FIG. 2 shows transmissivity (upper line) and reflectivity (lower line) data for uncoated 8 ohms/sq FTO. FIG. 3 shows transmissivity (upper line) and reflectivity (lower line) data for an 8 ohms/sq FTO coated with a 89 nm thick ITO film. FIG. 4 shows transmissivity (upper line) and reflectivity (lower line) data for an 8 ohms/sq FTO coated with a 68 nm thick ITO film. FIG. 5 shows transmissivity (upper line) and reflectivity (lower line) data for an 8 ohms/sq FTO coated with a 48 nm thick ITO film. As shown, the transmissivities for the uncoated FTO, FTO with 89 nm ITO, FTO with 68 nm ITO, and FTO with 48 nm ITO samples at 550 nm are respectively 81%, 83%, 82%, and 81%.

Table 3 shows data regarding surface roughness as a function of thickness. In this table, surface roughness is modeled from scanning ellipsometry data. It will be appreciated that surface roughness also may be a function of the method and apparatus used to deposit the precursor solution for forming the ITO film.

TABLE 3

| | Thickness of | Surface roughness |
|---|---|---|
| Sample Identity | ITO (nm) | (modeled) (nm) |
| Uncoated 8 ohms/sq FTO | N/A | 33.5 +/− 0.2 |
| Coated 8 ohms/sq FTO | 39 +/− 4 | 10.3 +/− 0.9 |
| Coated 8 ohms/sq FTO | 76 +/− 16 | 6 +/− 1 |
| Coated 8 ohms/sq FTO | 93 +/− 17 | 1.6 +/− 0.4 |

As shown in Table 3, the application of the ITO film over the FTO film substantially decreased surface roughness. This may help to avoid losses due to refraction, and thus may help to increase an efficiency of a solar cell, display system, or other optical system.

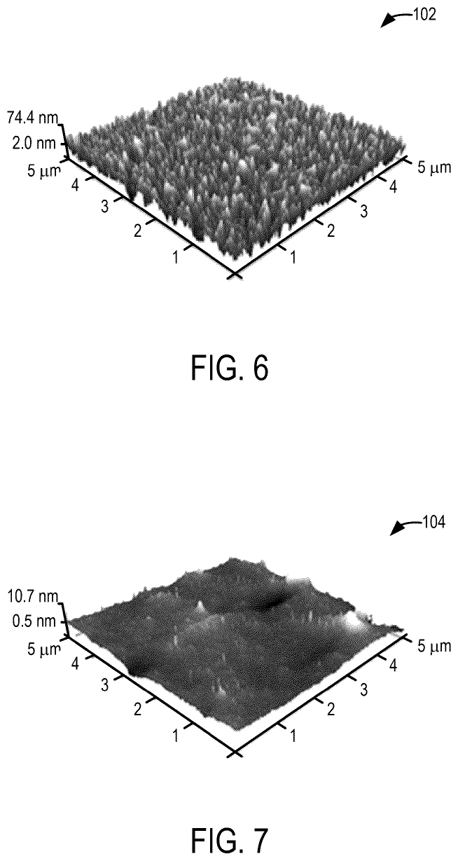

FIG. 6 shows an image of atomic force microscopy (AFM) data for an uncoated 8 ohms/sq FTO film 102. FIG. 7 shows an image of AFM data for a coated FTO film 104 comprising 8 ohms/sq FTO coated with an ITO film having a thickness of 93+/−17 nm. As shown, the coated FTO film 104 has a measured maximum roughness of 4 nm, compared to 49 nm for the uncoated FTO film 102.

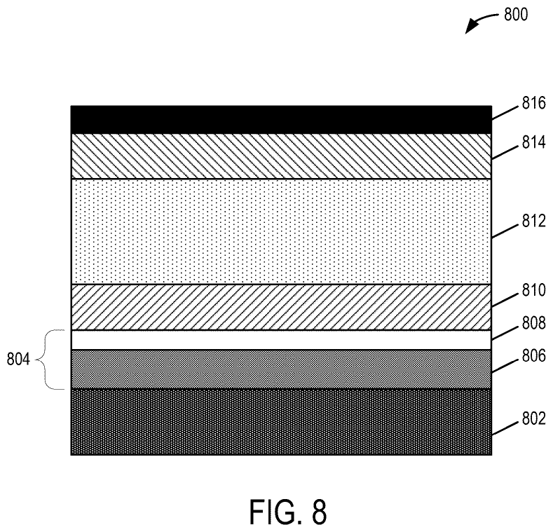

FIG. 8 shows an example solar cell 800 comprising a TCO film stack 804 formed on a substrate 802. Substrate 802 can comprise any suitable material, such as a glass. In some examples, the substrate 802 is a hydrophobic or hydrophilic glass, such as silicate glass. In other examples, the substrate 802 comprises a silicon wafer. The TCO film stack 804 comprises an FTO film 806 and a film of transparent conductor 808 deposited on the FTO film 806. In other examples, a film of ATO or AZO can be used in place of FTO film 806. The film of transparent conductor 808 can comprise any suitable material, such as Sn:In₂O₃, Ti:In₂O₃, Cd₂SnO₄, or a combination of two or more such materials. Solar cell 800 further comprises an electron transport layer 810 on the TCO film stack 804, and a photoactive layer 812 on the electron transport layer 810. In some examples, photoactive layer 812 comprises a perovskite material, such as a methylammonium lead halide or an inorganic cesium lead halide. In other examples, photoactive layer 812 comprises cadmium telluride. Solar cell 800 further comprises a hole transport layer 814 on photoactive layer 812, and a metal conductor layer 816 on the hole transport layer 814. The metal conductor layer 816 can comprise any suitable metal conductor, such as silver or gold.

In some examples, the TCO film stack 804 comprises a sheet resistance of between 6-8 ohms/square and a thickness of 300 nm or less. Further, in some examples, the film of transparent conductor 808 alternatively or additionally comprises a surface roughness of less than 20 nm. Also, in some such examples, the film of transparent conductor 808 alternatively or additionally comprises a surface roughness of less than 10 nm.

Another example provides an optical device comprising a substrate, a fluorine-doped tin oxide (FTO) film on the substrate, and a film of a transparent conductor on the FTO film. In some such examples, the optical device comprises a solar cell. In some such examples, the optical device comprises a display. In some such examples, the film of the transparent conductor additionally or alternatively comprises an indium tin oxide film. In some such examples, the film of the transparent conductor additionally or alternatively comprises one or more of Sn:In₂O₃, Ti:In₂O₃, or Cd₂SnO₄. In some such examples, the film of the transparent conductor additionally or alternatively comprises a sheet resistance of between 6-8 ohms/square and a thickness of 300 nm or less. In some such examples, the film of the transparent conductor additionally or alternatively comprises a surface roughness of less than 20 nm. In some such examples, the film of the transparent conductor additionally or alternatively comprises a surface roughness of less than 10 nm.

Another example provides a method of coating a FTO film on a substrate with a transparent conductive film. The method comprises applying a precursor solution to the FTO film, the precursor solution comprising one or more of indium/tin, indium/titanium, or cadmium/tin, heating the substrate comprising the precursor solution on the FTO film to cure the precursor solution and form the transparent conductive film, and annealing the substrate comprising the FTO film and the transparent conductive film. In some such examples, applying the precursor solution comprises applying the precursor solution by one or more of slot-die coating, dip coating, doctor blade coating, and spin coating. In some such examples, annealing the substrate additionally or alternatively comprises annealing the substrate in a reducing environment. In some such examples, heating the substrate to cure the precursor solution additionally or alternatively comprises heating the substrate under air. In some such examples, the precursor solution additionally or alternatively comprises one or more of indium nitrate, indium fluoride, indium chloride, indium bromide, or indium iodide. In some such examples, the precursor solution additionally or alternatively comprises one or more of tin fluoride, tin chloride, tin bromide, tin iodide, tin chloride hydrate, tin nitrate, tin nitrate hydrate, tin acetate, or tin sulfate. In some such examples, the precursor solution additionally or alternatively comprises one or more of cadmium fluoride, cadmium chloride, cadmium bromide, cadmium iodide.

Another example provides a solar cell comprising a glass substrate and a transparent conductive oxide film stack on the glass substrate, the transparent conductive oxide film stack comprising a fluorine-doped tin oxide (FTO) film on the perovskite substrate, and a film of a transparent conductor on the FTO film. The solar cell further comprises an electron transport layer on the film of the transparent conductor of the conductive oxide film stack and a photoactive layer on the electron transport layer. In some such examples, wherein the film of the transparent conductor comprises an indium tin oxide film. In some such examples, the film of the transparent conductor additionally or alternatively comprises one or more of Sn:In₂O₃, Ti:In₂O₃, or Cd₂SnO₄. In some such examples, the transparent conductive oxide film stack additionally or alternatively comprises a sheet resistance of between 6-8 ohms/square and a thickness of 300 nm or less. In some such examples, the film of the transparent conductor additionally or alternatively comprises a surface roughness of less than 20 nm.

1. An optical device, comprising:
a substrate;
a fluorine-doped tin oxide (FTO) film on the substrate; and
a film of a transparent conductor on the FTO film.

2. The optical device of claim 1, wherein the optical device comprises a solar cell.

3. The optical device of claim 1, wherein the optical device comprises a display.

4. The optical device of claim 1, wherein the film of the transparent conductor comprises an indium tin oxide film.

5. The optical device of claim 1, wherein the film of the transparent conductor comprises one or more of Sn:In₂O₃, Ti:In₂O₃, or Cd₂SnO₄.

6. The optical device of claim 1, wherein the film of the transparent conductor comprises a sheet resistance of between 6-8 ohms/square and a thickness of 300 nm or less.

7. The optical device of claim 1, wherein the film of the transparent conductor comprises a surface roughness of less than 20 nm.

8. The optical device of claim 7, wherein the film of the transparent conductor comprises a surface roughness of less than 10 nm.

9. A method of coating a fluorine-doped tin oxide (FTO) film on a substrate with a transparent conductive film, the method comprising:
applying a precursor solution to the FTO film, the precursor solution comprising one or more of indium/tin, indium/titanium, or cadmium/tin;
heating the substrate comprising the precursor solution on the FTO film to cure the precursor solution and form the transparent conductive film; and
annealing the substrate comprising the FTO film and the transparent conductive film.

10. The method of claim 9, wherein applying the precursor solution comprises applying the precursor solution by one or more of slot-die coating, dip coating, doctor blade coating, and spin coating.

11. The method of claim 9, wherein annealing the substrate comprises annealing the substrate in a reducing environment.

12. The method of claim 9, wherein heating the substrate to cure the precursor solution comprises heating the substrate under air.

13. The method of claim 9, wherein the precursor solution comprises one or more of indium nitrate, indium fluoride, indium chloride, indium bromide, or indium iodide.

14. The method of claim 9, wherein the precursor solution comprises one or more of tin fluoride, tin chloride, tin bromide, tin iodide, tin chloride hydrate, tin nitrate, tin nitrate hydrate, tin acetate, or tin sulfate.

15. The method of claim 9, wherein the precursor solution comprises one or more of cadmium fluoride, cadmium chloride, cadmium bromide, cadmium iodide.

16. A solar cell, comprising:
a glass substrate;
a transparent conductive oxide film stack on the glass substrate, the transparent conductive oxide film stack comprising
a fluorine-doped tin oxide (FTO) film on the perovskite substrate, and
a film of a transparent conductor on the FTO film;
an electron transport layer on the film of the transparent conductor of the conductive oxide film stack; and
a photoactive layer on the electron transport layer.

17. The solar cell of claim 16, wherein the film of the transparent conductor comprises an indium tin oxide film.

18. The solar cell of claim 16, wherein the film of the transparent conductor comprises one or more of Sn:In₂O₃, Ti:In₂O₃, or Cd₂SnO₄.

19. The solar cell of claim 16, wherein the transparent conductive oxide film stack comprises a sheet resistance of between 6-8 ohms/square and a thickness of 300 nm or less.

20. The solar cell of claim 16, wherein the film of the transparent conductor comprises a surface roughness of less than 20 nm.
